(19) United States
(12) Patent Application Publication
(10) Pub. No.: US 2008/0277675 A1
(43) Pub. Date: Nov. 13, 2008

(54) LIGHT-EMITTING DIODE ASSEMBLY WITHOUT SOLDER

(75) Inventor: Joseph C. Fjelstad, Maple Valley, WA (US)

Correspondence Address: The TPL Group, 20400 Stevens Creek Blvd., Fifth Floor, Cupertino, CA, 95014, US

(73) Assignee: OCCAM PORTFOLIO LLC, Cupertino, CA (US)

(21) Appl. No.: 12/119,342

(22) Filed: May 12, 2008

Related U.S. Application Data
(63) Continuation of application No. PCT/US08/63130, filed on May 8, 2008.
(60) Provisional application No. 60/928,467, filed on May 8, 2007.

(51) Int. Cl. H01L 33/00

(52) U.S. Cl. 257/88; 438/27; 257/E33.067; 257/E33.075

(57) ABSTRACT

An electrical device in the form of a light emitting diode (LED) assembly. A plurality of LEDs are provided, wherein each has an anode and a cathode. A base holds this plurality of LEDs in a substantially fixed relationship. One or more anode conductors then each connect electrically to one or more of the LED anodes in a manner characterized by not including any solder material. Similarly, one or more cathode conductors each connect electrically to one or more of the LED cathodes in a manner characterized by not including any solder material.

### CROSS-REFERENCE TO RELATED APPLICATIONS

This is a continuation of Application No. PCT/US08/63130, filed May 8, 2008, which claims the benefit of U.S. Provisional Application No. 60/928,467, filed May 8, 2007, all hereby incorporated by reference in their entirety.

### STATEMENT REGARDING FEDERALLY SPONSORED RESEARCH OR DEVELOPMENT

Not applicable.

### THE NAMES OF THE PARTIES TO A JOINT RESEARCH AGREEMENT

Not applicable.

### INCORPORATION-BY-REFERENCE OF MATERIAL SUBMITTED ON A COMPACT DISC

Not applicable.

### COPYRIGHT NOTICE AND PERMISSION

A portion of the disclosure of this patent document contains material which is subject to copyright protection. The copyright owner has no objection to the facsimile reproduction by anyone of the patent document or the patent disclosure, as it appears in the Patent and Trademark Office patent file or records, but otherwise reserves all copyright rights whatsoever.

### BACKGROUND OF THE INVENTION

1. Technical Field

The present invention relates generally to light-emitting diode (LED) arrays and the assembly thereof, and more particularly, but not exclusively, to such without the use of solder.

2. Background Art

The assembly of electronic products and more specifically the permanent assembly of electronic components to printed circuit boards, has involved the use of some form of relatively low temperature solder alloy (e.g., tin/lead or Sn63/Pb37) since the earliest days of the electronics industry. The reasons are manifold but the most important one has been the ease of mass joining of thousand of electronics interconnections between printed circuit and the leads of many electronic components.

Lead is a highly toxic substance, exposure to which can produce a wide range of well known adverse health effects. Of importance in this context, fumes produced from soldering operations are dangerous to workers. The process may generate a fume which is a combination of lead oxide (from lead based solder) and colophony (from the solder flux). Each of these constituents has been shown to be potentially hazardous. In addition, if the amount of lead in electronics were reduced, it would also reduce the pressure to mine and smelt it. Mining lead can contaminate local ground water supplies. Smelting can lead to factory, worker, and environmental contamination.

Reducing the lead stream would also reduce the amount of lead in discarded electronic devices, lowering the level of lead in landfills and in other less secure locations. Because of the difficulty and cost of recycling used electronics, as well as lax enforcement of legislation regarding waste exports, large amounts of used electronics are sent to countries such as China, India, and Kenya, which have lower environmental standards and poorer working conditions.

Thus, there are marketing and legislative pressures to reduce tin/lead solders. In particular, the Directive on the Restriction of the Use of Certain Hazardous Substances in Electrical and Electronic Equipment (commonly referred to as the Restriction of Hazardous Substances Directive or RoHS) was adopted in February 2003 by the European Union. The RoHS directive took effect on Jul. 1, 2006, and is required to be enforced and become law in each member state. This directive restricts the use of six hazardous materials, including lead, in the manufacture of various types of electronic and electrical equipment. It is closely linked with the Waste Electrical and Electronic Equipment Directive (WEEE) 2002/96/EC which sets collection, recycling and recovery targets for electrical goods and is part of a legislative initiative to solve the problem of huge amounts of toxic electronic device waste.

RoHS does not eliminate the use of lead in all electronic devices. In certain devices requiring high reliability, such as medical devices, continued use of lead alloys is permitted. Thus, lead in electronics continues to be a concern. The electronics industry has been searching for a practical substitute for tin/lead solders. The most common substitutes in present use are SAC varieties, which are alloys containing tin (Sn), silver (Ag), and copper (Cu).

SAC solders also have significant environmental consequences. For example, mining tin is disastrous both locally and globally. Large deposits of tin are found in the Amazon rain forest. In Brazil, this has led to the introduction of roads, clearing of forest, displacement of native people, soil degradation, creation of dams, tailing ponds, and mounds, and smelting operations. Perhaps the most serious environmental impact of mining tin in Brazil is the silting up of rivers and creeks. This degradation modifies forever the profile of animal and plant life, destroys gene banks, alters the soil structure, introduces pests and diseases, and creates an irrecoverable ecological loss.

Worldwide ecological problems stemming from mismanagement of Brazil's environment are well known. These range from pressures on global warming from the destruction of rain forest to the long term damage to the pharmaceutical industry by the destruction of animal and plant life diversity. Mining in Brazil is simply one example of the tin industry's destructive effects. Large deposits and mining operations also exist in Indonesia, Malaysia, and China, developing countries where attitudes toward economic development overwhelm concerns for ecological protection.

SAC solders have additional problems. They require high temperatures, wasting energy, are brittle, and cause reliability problems. The melting temperature is such that components and circuit boards may be damaged. This is a very important concern for certain types of light emitting components such as LEDs because the melt temperature of the epoxies used have difficulty withstanding the temperature required for assembly. Moreover, it is especially troublesome to assembly the devices to heat spreading substrates such are desirably used to draw heat away from the components in operation.

Correct quantities of individual alloy constituent compounds are still under investigation and the long term stability is unknown. Moreover, SAC solder processes are prone to the formation of shorts (e.g., “tin whiskers”) and opens if surfaces are not properly prepared. Whether tin/lead solder or a SAC variety is used, dense metal adds both to the weight and height of circuit assemblies.

Therefore there is a need for a substitute for the soldering process and its attendant environmental and practical drawbacks.

While solder alloys have been most common, other joining materials have been proposed and/or used such as so-called “polymer solders” which are a form of conductive adhesive. Moreover, there have been efforts to make connections separable by providing sockets for components. There have also been electrical and electronic connectors developed to link power and signal carrying conductors described with various resilient contact structures all of which require constant applied force or pressure.

At the same time, there has been a continual effort to put more electronics into ever smaller volumes. As a result, over the last few years there has been interest within the electronics industry in various methods for integrated circuit (IC) chip stacking within packages and the stacking of IC packages themselves, all with the intent of reducing assembly size in the Z or vertical axis. This is no less important for LED assemblies for lighting applications.

There has also been an ongoing effort to reduce the number of surface mounted components on a printed circuit board (PCB) by embedding certain components, mostly passive devices, inside the circuit board.

In the creation of IC packages, there has also been an effort to embed active devices by placing unpackaged IC devices directly inside a substrate and interconnecting them by drilling and plating directly to the chip contacts. While such solutions offer benefits in specific applications, the input/output (I/O) terminals of the chip can be very small and very challenging to make such connections accurately. The method is less practical for LED's because they must be packaged first to determine if they operate. Moreover the device after manufacturing may not successfully pass burn in testing making the entire effort valueless after completion.

Another area of concern is in management of heat as densely packaged semiconductor devices, such as LEDs, may create a high energy density that can reduce the reliability of assembly.

### BRIEF SUMMARY OF THE INVENTION

Accordingly, it is an object of the present invention to provide an improved light emitting diode (LED) assembly.

Briefly, one preferred embodiment of the present invention is an electrical device in the form of a light emitting diode (LED) assembly. A set of multiple LEDs are provided, wherein each has an anode and a cathode. A base holds the LEDs in a substantially fixed relationship, while one or more anode conductors connect electrically to one or more of the LED anodes in a manner characterized by not including any solder material. Similarly, one or more cathode conductors each connect electrically to one or more of the LED cathodes, also in a manner characterized by not including any solder material.

Briefly, another preferred embodiment of the present invention is a process for making an assembly of multiple light emitting diodes (LEDs), wherein each LED has an anode and a cathode. The LEDs are affixed to a base in a substantially fixed relationship. The LED anodes are each electrically connected to an anode conductor, wherein one or more of the anode conductors may be present and the connecting of them to the anodes is done in a manner characterized by not including any solder material. Similarly, the LED cathodes are each electrically connected to a cathode conductor, also wherein one or more of the cathode conductors may be present and the connecting of them to the cathodes is also done in a manner characterized by not including any solder material.

Entire sets of advantages of the present invention are derived from its elimination of the use of solder in LED assemblies and of soldering in the manufacture of LED assemblies.

An advantage from the elimination of the use of solder is that the metals in solder are no longer needed in LED assemblies. Historically these metals have tended to be simply expensive. Of particular present interest, however, the present invention can reduce the environmental costs of LED assemblies. Mining, refining, handling, and ultimately disposing of the metals in solder all tend to harm the environment and those who are in any way involved with these tasks.

An advantage from the elimination of the use of soldering to make LED assemblies is that direct and peripheral operations and costs related to it are no longer needed. Soldering necessarily involves heating the work pieces being soldered. Generally, handling heat, by applying and removing it as needed, tend to complicate and make manufacturing more expensive. In the case of LED assemblies, heat tends to damage the elements of the assemblies and applying and removing heat in the process of soldering especially tends to stress and further damage LED assemblies. Furthermore, once soldering is finished, one or more stages of clean up are frequently required, often using chemicals that are expensive and that also tend to be environmentally damaging.

And another advantage from the elimination of the use of solder and soldering to make LED assemblies is that the end product may be made more compact. Since solder between work pieces, such as the terminals of LEDs and their power feed conductors necessarily must occupy some space, eliminating the solder can free up this space. Additionally, solder connection tends to be “fat” since surface tension and flow effects when solder is liquid cause it to ultimately occupy more space than just the necessary junctures of the work pieces. Use of the present invention can therefore eliminate the need to oversize component “footprints.”

These and other objects and advantages of the present invention will become clear to those skilled in the art in view of the description of the best presently known mode of carrying out the invention and the industrial applicability of the preferred embodiment as described herein and as illustrated in the figures of the drawings.

### BRIEF DESCRIPTION OF THE SEVERAL VIEWS OF THE DRAWING(S)

The purposes and advantages of the present invention will be apparent from the following detailed description in conjunction with the appended figures of drawings in which:

FIG. 1 (background art) is a cross-section side view of a typical LED which may be used in either conventional LED assemblies or in LED assemblies that are in accord with the present invention.

FIG. 2 (prior art) is a cross-section side view of a conventional LED assembly that includes the LED of FIG. 1.

FIG. 3 is a cross-section side view of a LED assembly that is in accord with the present invention.

FIG. 4 is a cross-section side view of an alternate LED assembly that is also in accord with the present invention.

FIG. 5 is a cross-section side view of a larger LED assembly that is in accord with the present invention.

FIG. 6a-b are views of a yet larger LED assembly that is in accord with the present invention, wherein FIG. 6a is a top plan view of the LED assembly and FIG. 6b is a side cross-section view of the LED assembly.

FIGS. 7a-b show in perspective a large three-dimensional LED assembly that is in accord with the present invention, wherein FIG. 7a depicts the LED assembly with normal element relationships and FIG. 7b depicts the LED assembly partially exploded.

FIGS. 8a-j are cross-section side views of a LED assembly in a series of stages of manufacture.

FIGS. 9a-e are cross-section side views of an alternate LED assembly in a series of stages of manufacture.

In the various figures of the drawings, like references are used to denote like or similar elements or steps.

### DETAILED DESCRIPTION OF THE INVENTION

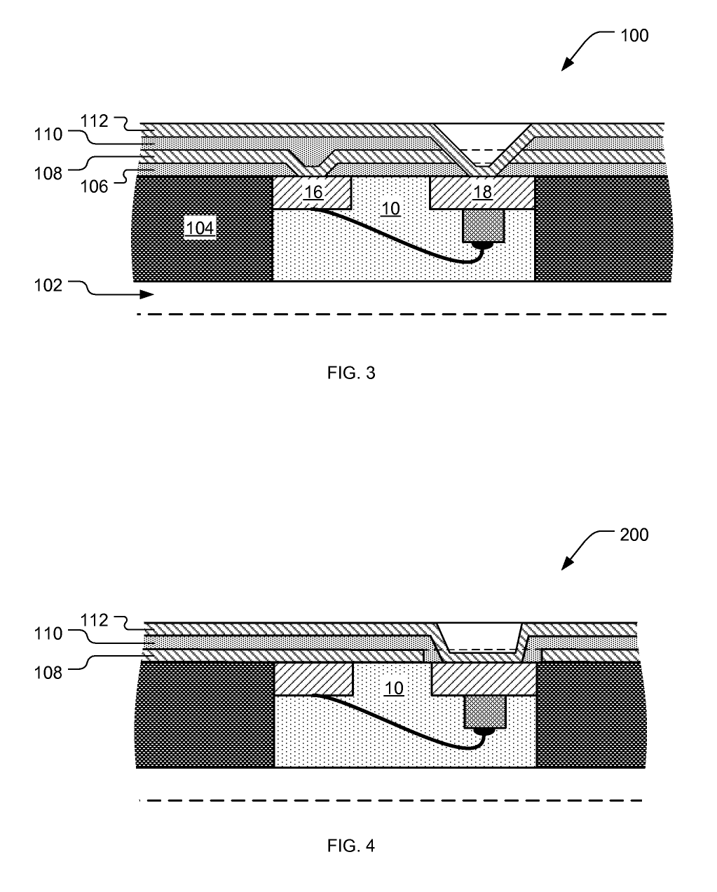

A preferred embodiment of the present invention is a light emitting diode (LED) assembly. As illustrated in the various drawings herein, and particularly in the view of FIG. 3, preferred embodiments of the invention are depicted by the general reference characters 100, 200, 300, 400, 500, 600, and 700.

FIG. 1 (background art) is a cross-section side view of a typical LED 10 which may be used in either conventional LED assemblies or in LED assemblies that are in accord with the present invention. The LED 10 has a body 12 that fills multiple roles. For example, the body 12 physically holds the other elements of the LED 10 in fixed relationships. This serves to protect the internal elements of the LED 10 from damage, to place the externally communicating elements of the LED 10 as needed, and to generally facilitate handling of the LED 10 when mounting it into a LED assembly. The body 12 also optically serves to generally pass the light wavelengths that the LED 10 emits. For this the body 12 particularly has a face 14 where light primarily emitted from the LED 10. At the face 14 the body 12 may optionally include features (not shown) like a lens to direct the light and/or a housing to mate with an external receiving light element (e.g., with an optical fiber). The body 12 may also serve to conduct heat away from internal elements of the LED 10. Historically this thermally conductive role has usually not been an important one, but that is now changing, especially for emerging high power LED applications. In view of all of these roles, the body 12 of the LED 10 is typically a plastic single material, with glass, quartz, or hybrids of materials also sometimes being used.

The external elements of the LED 10 other than the body 12 are an anode 16 and a cathode 18. The internal elements of the LED 10 are a top contact 20, a P-layer 22, a P—N junction 24, a N-layer 26, and a bottom contact 28. In the LED 10 shown in FIG. 1 an anode lead 30 is additionally provided that connects the top contact 20 to the anode 16, and the bottom contact 28 is integral with the cathode 18. In FIG. 1 the anode 16 and the cathode 18 are shown as contacts (or “pads” or “terminals”), but this is not the case for all LEDs and leads (or “wires”) are also common. For that matter, it should be kept in mind that the LED 10 is merely representative of LEDs in general.

In operation the LED 10 accepts a current into the anode 16, through the anode lead 30 to the top contact 20 and into the P-layer 22, across the P-N junction 24, into the N-layer 26 to the bottom contact 28, and out the cathode 18. This causes the LED 10 to generate light in its characteristic manner in the plane the P-N junction 24. It should be noted that this edge-emitting characteristic of the LED 10 can motivate designing the body 12 (or adding additional structure to it) to direct the light more optimally out the face 14 of the LED 10.

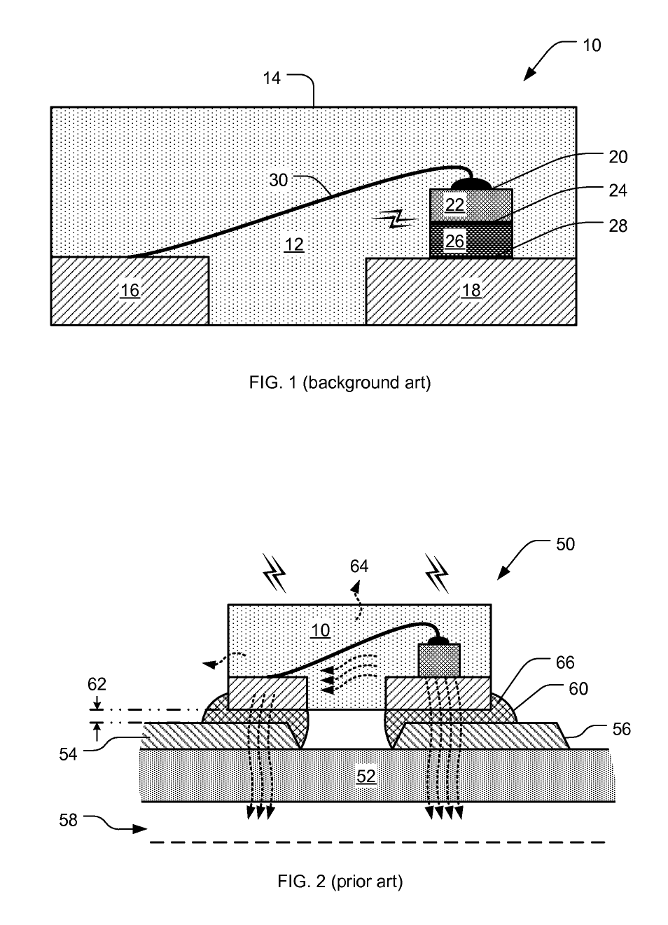

FIG. 2 (prior art) is a cross-section side view of a conventional LED assembly 50 that includes the LED 10 of FIG. 1. The LED assembly 50 here is oriented as it is typically manufactured and as it is often used, that is with the light emitting face 14 of the LED 10 upward.

In this orientation the LED assembly 50 is now discussed as generally being “built” from the bottom up. An electrically insulting substrate 52 is usually always provided, if for no other reason than to physically support an anode trace 54 and a cathode trace 56 as shown. However, optional elements may be provided in a sub-region 58 below the substrate 52. For example, if the substrate 52 is the top most non-conductive layer of a printed circuit board (PCB), other layers may also be present in this sub-region 58 (e.g. a ground plane or “reverse side” features if the printed circuit board is double sided).

For some emerging applications a feature that may particularly be present in the sub-region 58 below the substrate 52 is a heat spreader. The substrate 52 will typically serve to some extent to transfer heat, but it may not be optimal for that. To clarify, the role of a heat sink (which many in the art are more familiar with) and that of a heat spreader are different. Although these elements operate similarly to some extent, a head sink is optimized to remove thermal energy from a particular location, typically a point or small location, whereas a head spreader is optimized to distribute and equalize thermal energy across an area or large location.

Continuing with FIG. 2, the anode trace 54 and the cathode trace 56 are located above the substrate 52. Again, the common PCB serves as a useful example here. In a PCB the substrate 52 is usually an electrical insulating material, the traces 54, 56 are copper foil, and the necessary pattern of the traces 54, 56 on the substrate 52 is achieved with a silkscreen printing, photolithography, milling, or other suitable process.

Of particular interest herein is the next higher feature in the LED assembly 50, a set of solder pads 60. These electrically connect the anode trace 54 to the anode 16 and the cathode trace 56 to the cathode 18 of the LED 10. The solder pads 60 also physically connect the LED 10 to the rest of the LED assembly 50, thus holding the LED 10 in place.

The possible materials in the solder pads 60 have already been discussed elsewhere herein and are legend. It should further be observed here, however, that the solder pads 60 inherently add an additional level or displacement layer 62 to the overall LED assembly 50. In applications where the overall thickness of the LED assembly 50 is critical, this displacement layer 62 can be a concern and minimizing or eliminating it can then be an important goal.

FIG. 2 also stylistically shows thermal flow paths 64 out of the LED 10 and into the LED assembly 50. As can be seen here, much of the thermal energy produced by the LED 10 passes through the solder pads 60, with the majority of it flowing through the cathode 18 and the cathode trace 56. In some applications this thermal flow can cause serious problems. For example, if too much heat builds up in the LED 10 it may be damaged internally. The solder pads 60 tend to be thermally conductive, but they nonetheless lengthen and complicate the path that primary paths that thermal energy must travel to exit the LED 10. Furthermore, since the flow of thermal energy in the structures of the LED 10 and in the overall LED assembly 50 is not instantaneous, localized heating can result (e.g., at the cathode end of the LED 10 in FIG. 2). This can thermally stress the LED assembly 50, which in extreme situations can cause separation of a solder pad 60 from the anode 16, the cathode 18, or a trace 54, 56 or even fracture of the body 12 of the LED 10.

In FIG. 2 the thermal flow paths 64 out the top and sides of the LED 10 are minimal (as stylistically depicted with lesser weight arrows). There is little that can be done with respect to the top of the LED 10, since the face 14 of the LED 10 here needs to emit the light produced. But the sides of the LED 10 are another matter. Here however, the solder pads 60 tend to interfere with what can be done. Having the sides of the LED 10 open (as shown in FIG. 2) is desirable when the LED 10 is soldered into the LED assembly 50, especially in surface mount device (SMD) embodiments of the LED assembly 50 where surface tension effects of the liquid solder are relied on to help position the LED 10. But after soldering, wick regions 66 in the solder pads 60 (also caused by surface tension effects when the solder is liquid) usually remain and can interfere with adding a thermal conductor to the sides of the LED 10 once it is in the LED assembly 50.

Solder-based electronic assembly techniques have now served us for over a century and they have been used with LEDs for roughly half that time. Increasingly, however, as illustrated with the examples just discussed as well as many others, these techniques are falling short of our needs and new applications, especially ones with more powerful LEDs and large numbers of LEDs in close proximity, are now increasing our needs. In view of this the inventor has developed improved electronic assembly techniques, particularly including ones that are not solder-based.

FIG. 3 is a cross-section side view of a LED assembly 100 that is in accord with the present invention. In the interest of presenting the invention here clearly, without unduly introducing new detail that is not particularly relevant, the LED 10 of FIG. 1 is again used for the sake of example. Nonetheless, those skilled in the art will appreciate that many variations in LED design exist but that, by in large, altering the present invention to use other designs will be a relatively straightforward matter of design once the following principles are grasped.

The inventive LED assembly 100 is FIG. 3 is intentionally shown oriented opposite the prior art LED assembly 50 in FIG. 2. This facilitates discussion here of one way that the LED assembly 100 can be manufactured. Of course, the LED assembly 100 can be oriented as needed later in operation.

Accordingly, starting at the bottom in FIG. 3, an optional sub-region 102 may be provided (examples are discussed, presently). Next upward is the LED 10. Again, the example here uses the conventional LED 10 of FIG. 1, which has already been discussed in detail. Additionally however, the LED 10 here is shown surrounded with an optional matrix 104.

The matrix 104 can serve many roles. For example, it can assist in holding the LED 10 in place permanently or do this temporarily during early stages of assembly and later be removed. If the matrix 104 is part of the final LED assembly 100 it can also assist with equally distributing and removing thermal energy and in making the overall LED assembly 100 more robust. For instance, the matrix 104 can help the LED assembly 100 withstand physical strain and keep corrosive and shorting contaminants away from the anode 16 and the cathode 18 of the LED 10. The matrix 104 can also help in directing light out the face 14 of the LED 10. Recall that light is emitted edge-wise in the plane of the P-N junction 24, thus usually not directly toward the face 14 of the LED 10. With reference briefly back to FIG. 2, it can be appreciated that appreciable portions of the light produced here may exit at the sides rather than through the face 14 of the LED 10, even with the relative difference in the indices of refraction of the body 12 and the ambient region (typically air) around the LED 10. In contrast, the matrix 104 in FIG. 3 effectively prevents any light from exiting through the sides of the LED 10, and ensures that most of the light exits through the face 14 of the LED 10 as desired.

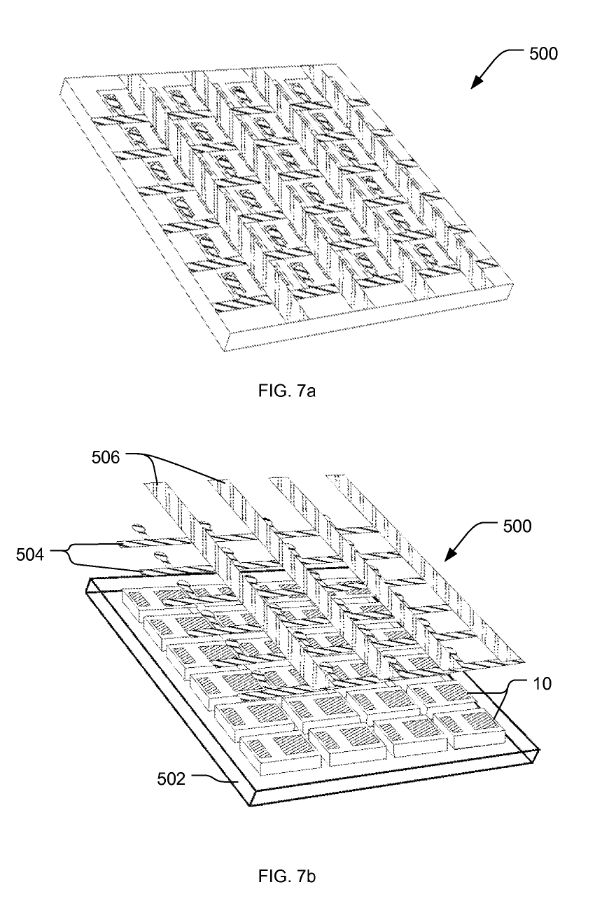

Continuing from the bottom up in FIG. 3, above the LED 10 here is a base 106, an anode conductor 108, an insulating layer 110, and a cathode conductor 112. Undue implied limitations in these layers here should not be assumed. For example, various manufacturing process can be used to create these conductor layers including electroless plating, electrolytic plating, sputtering, ultrasonic bonding of conductors (e.g. wires), resistance welding of conductors, conductor filled polymers (e.g. filled with metal powders or nano particles), similarly filled conductive inks, catalyzed inks, intrinsically conductive polymers. Functionally the results will be largely the same, but may vary considerably in structure. Related to this, it should also be kept in mind that the view in FIG. 3 is a side view and that interpreting it too hastily may lead to wrong impressions. For instance, the anode conductor 108 and the cathode conductor 112 here appear to be layers but they may instead merely be conductive lines or traces when the LED assembly 100 is viewed in three dimensions (see e.g., FIGS. 7a-b for an example that particularly illustrates this point).

The base 106 in embodiments such as that shown in FIG. 3 is an insulator to maintain electrical isolation between the anode 16 and the cathode 18 of the LED 10. Otherwise large orifices through the base 106 are needed at both the anode 16 and the cathode 18 or at one of these and then the base 106 degenerates into being either the anode conductor 108 or the cathode conductor 112. In particular, the base 106 can serve as a substrate for the upper layers in some manufacturing processes (e.g., photolithography) and/or it can serve as a heat spreader.

In contrast, the anode conductor 108 and the cathode conductor 112 both necessarily need to be conductive, since their primary roles are to conduct electrical current. The anode conductor 108 conducts current to the anode 16 of the LED 10 and the cathode conductor 112 conducts current from the cathode 18 of the LED 10. In FIG. 3 the anode conductor 108 is shown below the cathode conductor 112, but this is not a limitation and there is no reason that the opposite cannot be the case in alternate embodiments.

As its label implies, the insulating layer 110 needs to be an insulator, since its role is to electrically isolate the anode conductor 108 from the cathode conductor 112. Optionally, by appropriate material selection the insulating layer 110 can be optimized to assist as a heat spreader.

In general, the base 106 and the insulating layer 110 will be planar layers and one of the anode conductor 108 or the cathode conductor 112 can also be a planar layer, or both the anode conductor 108 and the cathode conductor 112 can simply be lineal conductors (again, see e.g., FIGS. 7a-b). If one of these conductors 108, 112 is planar, this can provide electromagnetic shielding. Additionally, since these electrically conductive conductors 108, 112 also tend to be thermally conductive, when one is planar it can also serve as a heat spreader.

FIG. 4 is a cross-section side view of an alternate LED assembly 200 that is also in accord with the present invention. Here no separate layer equivalent to the base in FIG. 3 is present. Instead the anode conductor 108 is serving as a base to the LED 10 in addition to its being a conductor. A direct variation of this would be to make the cathode conductor 112 the lower-most conductor and have it additionally serve as the base to the LED 10.

Up to this point simple one-LED embodiments have been used to introduce key principles of the present invention without obscuring things in too much detail. With these principles now covered, this discussion now turns to some examples that show how the present invention can particularly provide LED assemblies that include large numbers of LEDs.

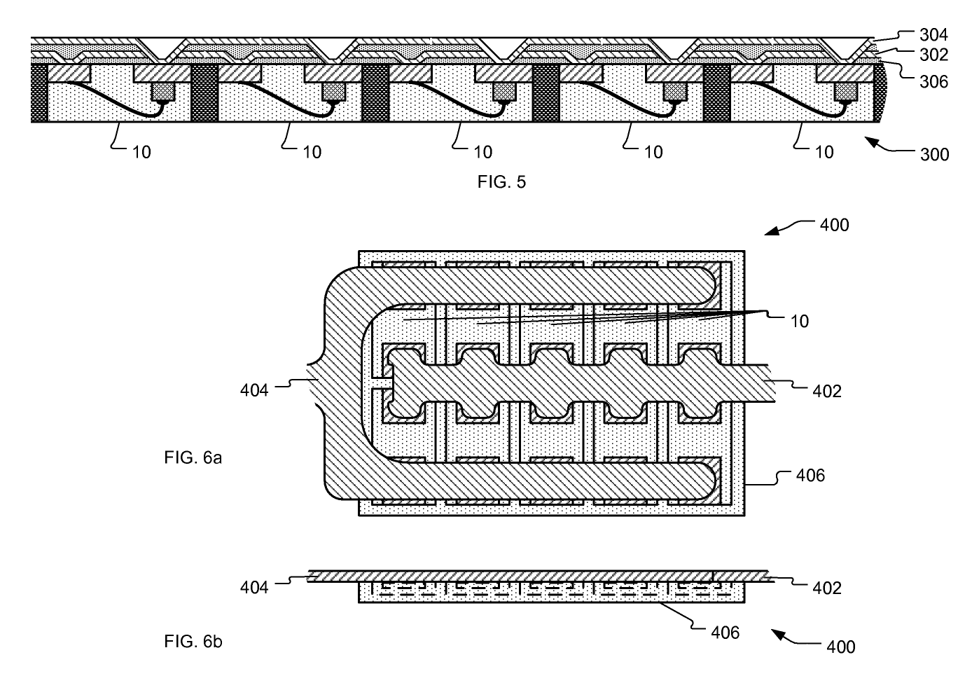

FIG. 5 is a cross-section side view of a larger LED assembly 300 that is in accord with the present invention. Five LEDs 10 are depicted here in a linear arrangement. In view of the preceding discussion, most of the features and operation of the LED assembly 300 should be straightforward. One new aspect that should be noted, however, is that a single anode layer 302 and a single cathode layer 304 are each common to all of the LEDs 10 here (and a common base 306 is used here as well). Accordingly, the LEDs 10 here all operate in unison, all being lit or dark concurrently. Those skilled in the art will readily appreciate, however, that multiple anode lines and/or multiple cathode lines, and appropriate insulating layers or equivalent mechanisms, can be provided and then the LEDs can be operated individually or commonly, as desired.

FIG. 6a-b are views of a yet larger LED assembly 400 that is in accord with the present invention, wherein FIG. 6a is a top plan view of the LED assembly 400 and FIG. 6b is a side cross-section view of the LED assembly 400. Ten LEDs 10 are depicted here in a two-lines of-five arrangement. Again, most of the features and operation of this LED assembly 400 should also be straightforward. A different aspect that should be noted, however, is that no insulating layer is provided here because both an anode conductor 402 and a cathode conductor 404 are in the same plane yet common to all of the LEDs 10 here. Another aspect that should be noted here is that either the anode layer 302 or the cathode layer 304 can be view as a “base” here, since both are common to all of the LEDs 10 and serve to some extent to support them. It can also be appreciated here, particularly from FIG. 6b, that the LED assembly 400 may be quite thin and have a very low side profile (e.g., thinner even than the prior art LED assembly 50 in FIG. 2).

Returning briefly to FIG. 5 and continuing with FIGS. 6a-b, these should not be misinterpreted as implying that the present invention can only be embodied in rigid geometries. For example, multiple LEDs 10 can be nominally ordered in a linear-like manner (as is the case in FIG. 5) yet be not literally in a geometrical line. For instance, twenty-five LEDs 10 could be physically arranged in a circle, an open-ended curve, a spiral, etc. Alternately, multiple LEDs 10 can be nominally ordered in an array-like manner (as is the case in FIG. 6a-b) yet not be literally placed in a geometrical plane. For instance, twenty-five LEDs 10 could also be physically arranged in a full or partial cylinder, a semi-sphere, or in any of many other three-dimensionally curved shapes.

FIGS. 7a-b show in perspective a large three-dimensional LED assembly 500 that is in accord with the present invention, wherein FIG. 7a depicts the LED assembly 500 with normal element relationships and FIG. 7b depicts the LED assembly 500 partially exploded.

Proceeding again from the bottom up with the LED assembly 500 here oriented as it might be during manufacturing, a transparent sub-layer 502 is provided and all of the LEDs 10 have their faces (not visible here see e.g., FIG. 1) against this sub-layer 502. The LEDs 10 here are all shown in like orientation here, i.e., all with anodes 16 to the left and cathodes 18 to the right, but this is not a requirement. For example, the LEDs 10 might instead be arranged so that the anodes 16 of two lines of LEDs 10 are adjacent (as in FIG. 6a), the cathodes 18 of two lines of LEDs 10 are adjacent, etc. This can facilitate laying out anode traces 504 and cathode traces 506 (used here in functionally the same manner as the anode conductor 108 and the cathode conductor 112 in FIGS. 3-5). The base 106 and the insulating layer 110 of FIGS. 3-5 are omitted here in FIGS. 7a-b to avoid their hiding other elements.

The anode traces 504 and cathode traces 506 here are a slight variation on the arrangement shown in FIG. 5. In FIGS. 7a-b some combinations of the LEDs 10 cannot be controllably powered. For example, a set of LEDs 10 extending diagonally form the bottom left to the top right cannot be powered without concurrently powering all of the LEDs 10 that are present. However, overcoming this is relatively straightforward. Similar to what was discussed above with respect to selectively operating individual LEDs in a liner assembly, address-ably powering the LEDs in a three-dimensional assembly merely requires changing the traces (typically adding additional ones) and insulating them.

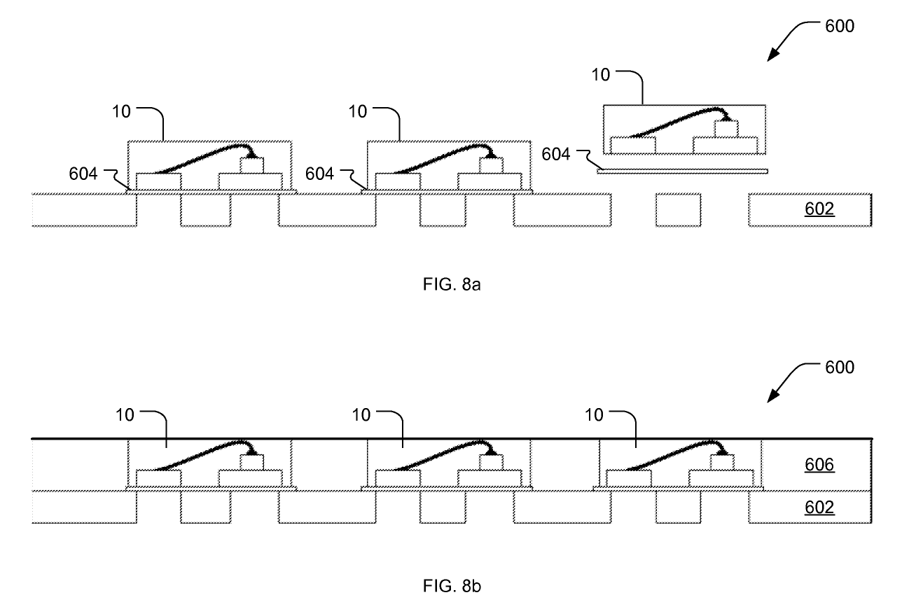

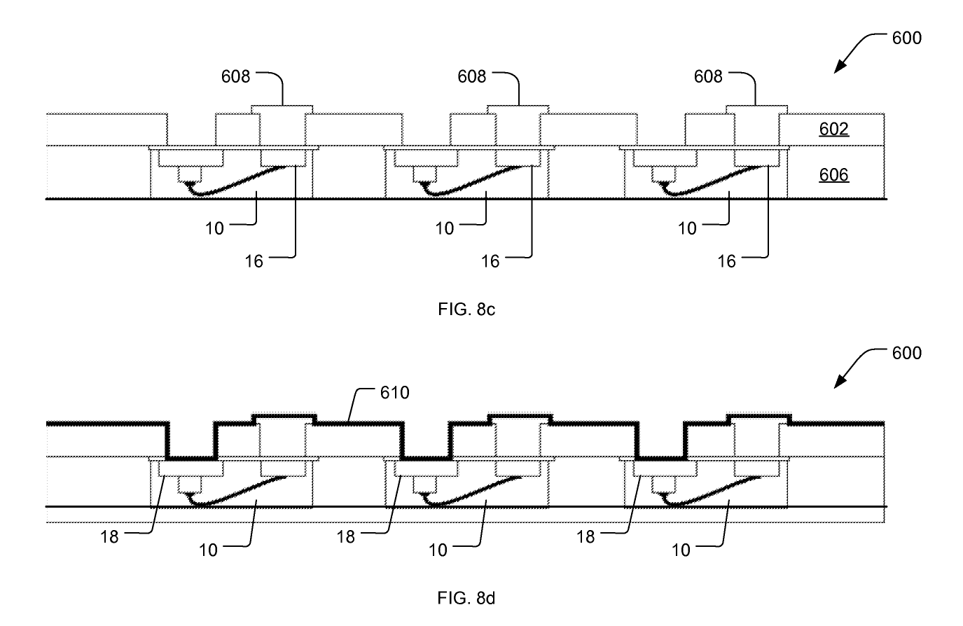

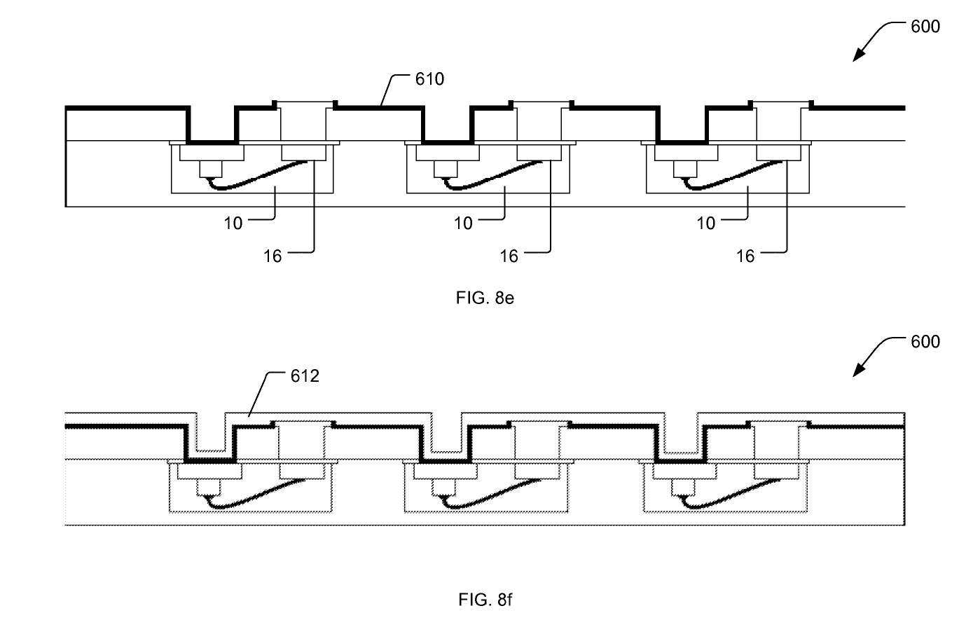

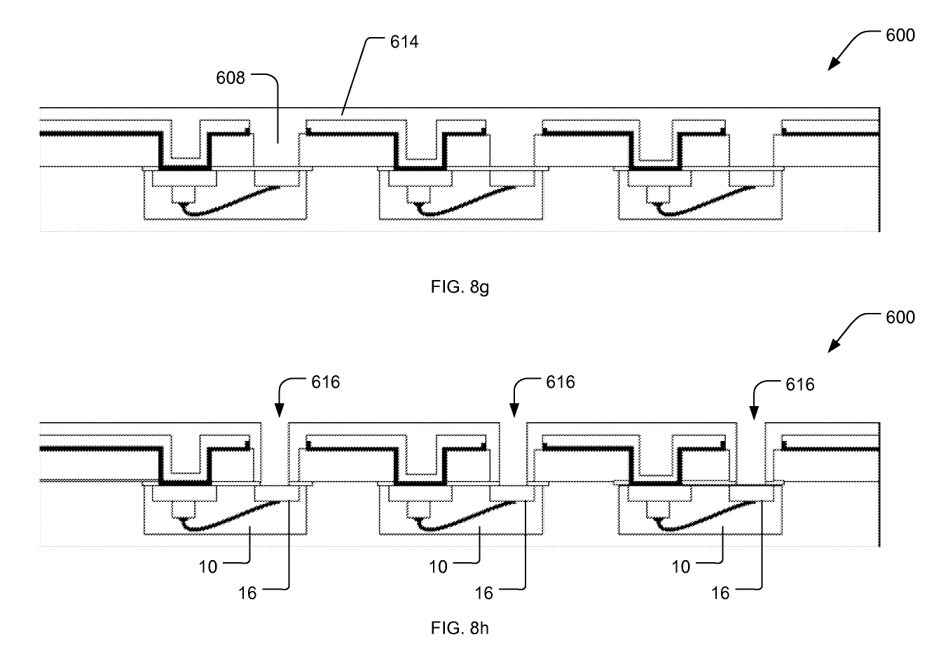

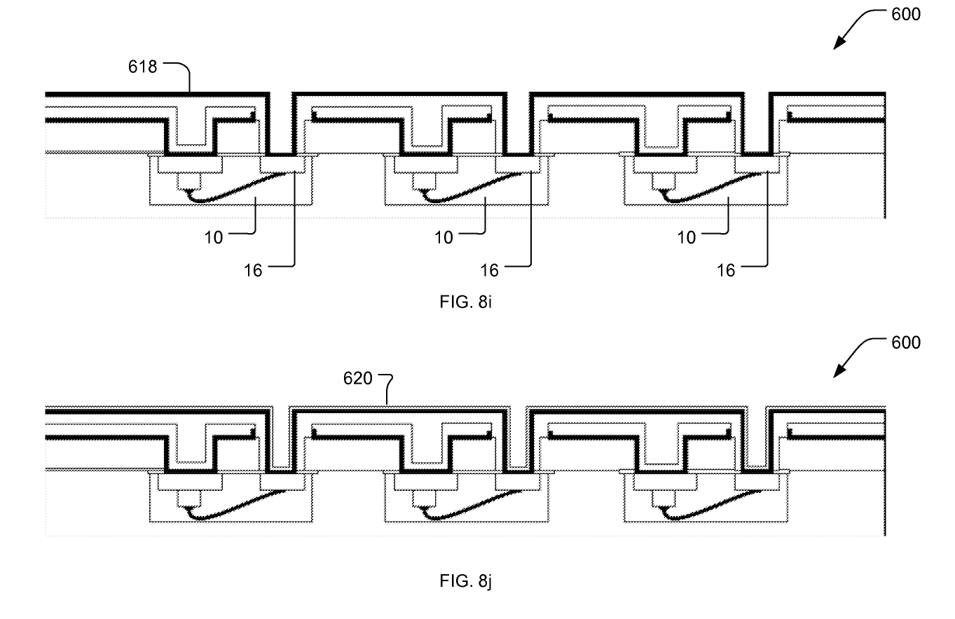

FIGS. 8a-j are cross-section side views of a LED assembly 600 in a series of stages of manufacture. In FIG. 8a a base 602 has been provided, some LEDs 10 have already been affixed to the base 602 with a bonding agent 604, and one LED 10 (the right most one) is in the process of being bonded to the base 602 with bonding agent 604. The base 602 here will typically be of an electrically insolating material, for reasons that will become evident presently. Secondarily, the base 602 here may also be of a thermally conductive material, if desired and to the extent that this does not unduly conflict with it being an electrical insulator. The bonding agent 604 here need not be an especially strong adhesive, since it is only relied on temporarily for bonding. However, the bonding agent 604 here necessarily is an electrical insulator, and it may be chosen to be of a material that it is thermally conductive as well.

In FIG. 8b all of the LEDs 10 have been affixed (bonded) to the base 602 and a cover layer 606 has been applied over the current top side of the LED assembly 600. This cover layer 606 is necessarily somewhat transparent (i.e., optically conductive) to the light wavelengths emitted by the LEDs 10, for the obvious reason that a substantial portion of the light emitted by the LEDs 10 should pass through the cover layer 606. If the cover layer 606 was made thinner, for instance, and not entirely covering the LEDs 10 and their faces 14 (FIG. 1), the cover layer 606 could then instead be of a non-transparent material. In some embodiments of the inventive LED assembly 600 one particularly suitable choice of material for the cover layer 606 is to have it be the very same material used in the bodies of the LEDs 10, since this will ensure that the indexes of refraction of the bodies of the LEDs 10 and of the cover layer 606 are essentially the same and that light travels efficiently from the LEDs 10 and into the cover layer 606 with minimal reflection and loss. In alternate embodiments of the inventive LED assembly 600, however, a material for the cover layer 606 that is different than that used in the bodies of the LEDs 10 may be intentionally chosen to diffuse the light from the LEDs 10, and thus more evenly emit the light from the LED assembly 600 as a whole. Another option for the cover layer 606 is to use a non-homogeneous material, for instance, one infused with small air or gas bubbles or with particles of silver or aluminum. The use of such a non-homogeneous material will then generally assist in diffusing light from the LED assembly 600. Additionally, recalling that the P—N junctions 24 (FIG. 1) in the LEDs 10 edge emit light, this helps better direct the light produced out the LED assembly 600 (i.e., upward with respect to the orientation of the LED assembly 600 as it is shown in FIG. 8a-b).

Continuing with respect to the material of the cover layer 606, this may also be one chosen to be thermally conductive. In the particular embodiment of the inventive LED assembly 600 here in FIGS. 8a-j, whether the material of the cover layer 606 is an electrical insulator is not important, but due consideration for this can be made for other embodiments.

In FIG. 8c the LED assembly 600 has been flipped over to facilitate adding materials in the remaining manufacturing stages, and a next stage has been performed where heat spreader regions 608 have been applied near the anodes 16 of the LEDs 10. The material put into these heat spreader regions 608 may optionally be the same as that of the bonding agent 604, as is the case depicted here.

In FIG. 8d a cathode layer 610 (or a set of cathode conductors or traces) has been applied. This electrically connects the cathodes 18 of the LEDs 10 shown here, and this cathode layer 610 will ultimately carry electrical current when the LED assembly 600 is in use, in the manner described elsewhere herein. The cathode layer 610 accordingly is an electrically conductive material (conductors are depicted with heavier weight lines in FIGS. 8a-j).

In FIG. 8e portions of the a cathode layer 610 above the anodes 16 of the LEDs 10 have been removed. And in FIG. 8f an insulator layer 612 has been applied.

In FIG. 8g a heat spreader layer 614 has been applied. This typically, but not necessarily will be the same material that is used in the heat spreader regions 608, as is the case depicted here.

In FIG. 8h orifices 616 have been provided to the anodes 16 of the LEDs 10, and in FIG. 8i an anode layer 618 (or a set of anode conductors or traces) has been applied that electrically connects the anodes 16 of the LEDs 10 shown here. This anode layer 618 will also ultimately carry electrical current when the LED assembly 600 is in use, in the manner described elsewhere herein.

Finally, in FIG. 8j an optional protective layer 620 has been applied. This typically will be of a physically hard and electrically insulating material. The LED assembly 600 here is now finished.

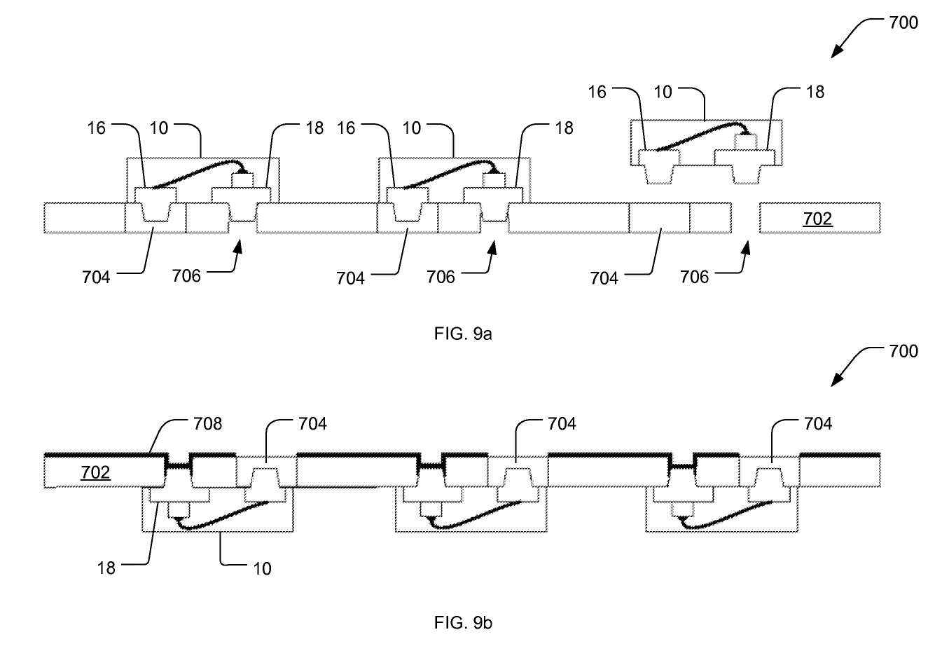

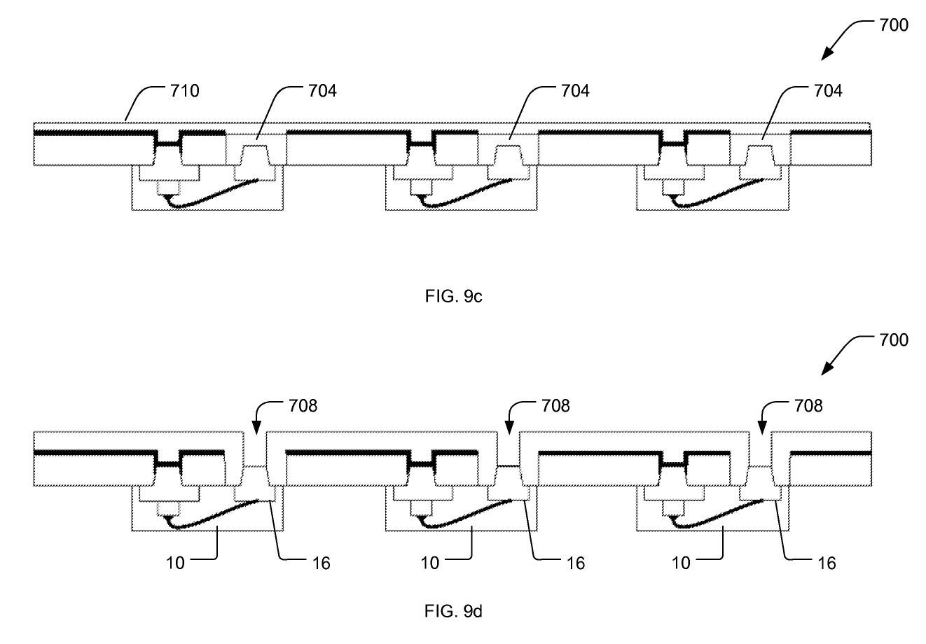

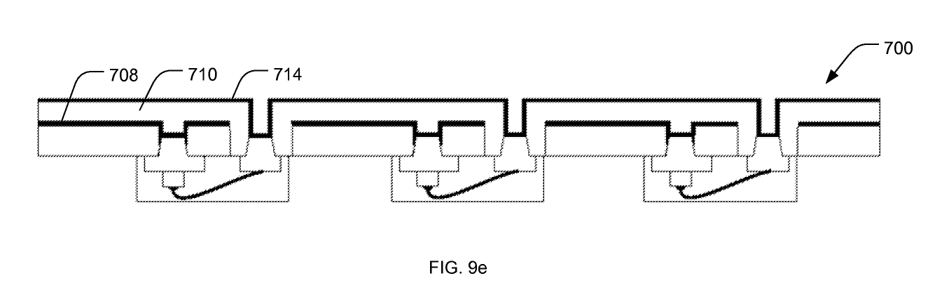

FIGS. 9a-e are cross-section side views of an alternate LED assembly 700 in a series of stages of manufacture. In FIG. 9a a base 702 has been provided, some LEDs 10 have already been placed (affixed) into the base 702, and one LED 10 is in the process of being placed. Here heat spreader regions 704 are provided which receive the anodes 16 of the LEDs 10, but these are not primarily relied on to hold the LEDs 10 in place. Instead the base 702 here already has orifices 706 that are sized so the cathodes 18 of the LEDs 10 engage with an interference fit. In FIG. 9a the LED assembly 700 is oriented with the LEDs 10 above the base 702 but this is entirely a matter of choice, since no equivalent to the cover layer 606 of the LED assembly 600 in FIGS. 8b-i is provided here.

In FIG. 9b the LED assembly 700 has been flipped over to facilitate adding materials in the remaining manufacturing stages. [Note, the orientation of assemblies during manufacture are not limitations of the present invention. There may or may not be an orientation that is best during a particular stage of a particular process, but dealing with this when applying the teachings herein to manufacture embodiments of the invention should be straightforward to one of ordinary skill in general manufacturing processes.]

In FIG. 9b a cathode layer 708 (or cathode conductor or trace) has also been applied over the base 702 and the cathode 18 of the LEDs 10 (conductors are depicted with heavier weight lines in FIGS. 9a-e). As can be seen here however, this cathode layer 708 does not also cover the heat spreader regions 704. This can be, for example, because the material of the cathode layer 708 is one that does not adhere to the material of the heat spreader regions 704, or the material of the cathode layer 708 can even be one that “shies away” from the material in the heat spreader regions 704 (e.g., due to intentionally chosen surface tension characteristics). Of course, the cathode layer 708 can also be applied over the heat spreader regions 704 and then removed selectively from those too (e.g., by laser ablation).

Digressing again briefly, in the specific arrangement shown for the LED assembly 700 in FIGS. 9a-e the cathode layer 708 can simply be dispensed with entirely if the base 702 is made of an electrically conductive material and used to carry current from the LEDs 10 in the manner of a cathode layer.

Continuing, in FIG. 9c a heat spreader layer 710 has been applied. This may (as shown) or may not be of the same material as the heat spreader regions 704.

In FIG. 9d orifices 712 have been provided to the anodes 16 of the LEDs 10. These orifices 712 might be termed “vias” in some manufacturing processes, but they can be obtained with laser, electron beam, or abrasive ablution, or with a photolithographic etch, or by any other suitable process. Accordingly, to avoid restrictive interpretation the broader term “orifice” is used herein.

Finally, in FIG. 9e an anode layer 714 (or anode conductor or trace) has been applied. The material or materials of the anode layer 714 and the cathode layer 708 are necessarily electrically conductive, and since the heat spreader layer 710 is in contact with both of these it follows that the heat spreader layer 710 here has to be of an electrically insulating material. The LED assembly 700 here is now finished.

While various embodiments have been described above, it should be understood that they have been presented by way of example only, and that the breadth and scope of the invention should not be limited by any of the above described exemplary embodiments, but should instead be defined only in accordance with the following claims and their equivalents.

What is claimed is:

1. An electrical device, comprising:
a plurality of light emitting diodes (LEDs), wherein each said LED has an anode and a cathode;
a base holding said plurality of LEDs in a substantially fixed relationship;
one or more anode conductors each connecting electrically to one or more said anodes of said LEDs in a manner characterized by not including any solder material; and
one or more cathode conductors each connecting electrically to one or more said cathodes of said LEDs in said manner characterized by not including any said solder material, thereby providing a LED assembly.

2. The device of claim 1, wherein:
one said anode conductor is present and is said base or one said cathode conductor is present and is said base.

3. The device of claim 1, further comprising:
an insulating layer separating said one or more anode conductors from said one or more cathode conductors.

4. The device of claim 1, further comprising:
a spreader layer to distribute heat from said plurality of LEDs throughout said LED assembly.

5. The device of claim 1, wherein each said LED has a face where light is desirably principally emitted and at least one lateral side other than where said anode and said cathode connect electrically, the device further comprising:
a matrix of material surrounding at least portions of said lateral sides of said plurality of LEDs.

6. The device of claim 5, wherein:
said matrix of material is of a type suitable to reflect said light at said lateral sides of said plurality of LEDs, thereby increasing said light emitted out said faces of said plurality of LEDs.

7. The device of claim 5, wherein:
said matrix of material surrounds said lateral sides of said plurality of LEDs entirely and further covers said faces of said plurality of LEDs.

8. The device of claim 5, wherein:
said matrix of material is of a type suitable to diffuse said light.

9. The device of claim 1, wherein:
said plurality of LEDs are arranged in a linear-like manner.

10. The device of claim 1, wherein:
said plurality of LEDs are arranged in an array-like manner.

11. A process for making an assembly of a plurality of light emitting diodes (LEDs), wherein each LED has an anode and a cathode, the process comprising:
(a) affixing the LEDs to a base in a substantially fixed relationship;
(b) electrically connecting the anodes of the LEDs each to an anode conductor, wherein one or more said anode conductors may be present and said connecting the anodes is in a manner characterized by not including any solder material; and
(c) electrically connecting the cathodes of the LEDs each to a cathode conductor, wherein one or more said cathode conductors may be present and said connecting the cathodes is in a said manner characterized by not including any said solder material.

12. The process of claim 11, wherein:
said base is an electrical insulator;
said (b) includes:
providing anode orifices through said base that access the anodes of the LEDs; and
depositing said anode conductors through said anode orifices; and
said (c) includes:
providing cathode orifices through said base that access the cathodes of the LEDs; and
depositing said cathode conductors through said cathode orifices.

13. The process of claim 11, further comprising:
routing said anode conductors and said cathode conductors seperatedly on said base.

14. The process of claim 11, further comprising:
(d) providing an insulating layer between said one or more said anode conductors and said one or more said cathode conductors.

15. The process of claim 14, wherein:
a single said anode conductor is present
said base is an electrical conductor and is said single said anode conductor;
said (c) includes:
providing clearance orifices through said base such that said base does not electrically connect with the cathodes of the LEDs; and
said (d) includes:
providing anode orifices through said insulating layer that access the anodes of the LEDs.

16. The process of claim 14, wherein:
a single said cathode conductor is present
said base is an electrical conductor and is said single said cathode conductor;
said (c) includes:
providing clearance orifices through said base such that said base does not electrically connect with the anodes of the LEDs; and
said (d) includes:
providing cathode orifices through said insulating layer that access the cathodes of the LEDs.

17. The process of claim 11, wherein:
one said anode conductor is present and is said base or one said cathode conductor is present and is said base.

18. The process of claim 11, wherein each said LED has a face where light is desirably principally emitted and at least one lateral side other than where said anode and said cathode connect electrically, the process further comprising:
surrounding said lateral sides of said plurality of LEDs with a light reflective material.

19. The process of claim 11, wherein each said LED has a face where light is desirably principally emitted and at least one lateral side other than where said anode and said cathode connect electrically, the process further comprising:
covering at least said faces of said plurality of LEDs with a light diffusing material.

20. An electrical device, comprising:
a plurality of light emitting diodes (LEDs), wherein each said LED has an anode and a cathode;
a base means for holding said plurality of LEDs in a substantially fixed relationship;
one or more anode conductor means to each electrically connect one or more said anodes of said LEDs in a manner characterized by not including any solder material; and
one or more cathode conductor means to each electrically connect to one or more said cathodes of said LEDs in said manner characterized by not including any said solder material, thereby providing a LED assembly.

21. An electrical device, comprising:
a plurality of light emitting diodes (LEDs), wherein each said LED has an anode and a cathode;
a base having a first plurality of apertures; and
one or more first conductors connected to either the anode or the cathodes of said LEDs through said first plurality of apertures.

22. The electrical device of claim 21, further including a second plurality of apertures in said base and one or more second conductors connected to one or more of said cathodes of said LEDs through the second plurality of apertures.

23. The electrical device of claim 21, wherein said plurality of apertures are arranged in a pattern.

24. The electrical device of claim 22, further including an insulating layer between said first and said second conductors.

25. The electrical device of claim 21, wherein said one or more conductors are selected from a group consisting of electrolessly plated metal, electrolytically plated metal; sputtered metal; ultrasonically bonded metal; resistance-welded metal; conductive polymers, and conductive inks.

26. The electrical apparatus of claim 21, wherein said base is composed of a thermally conductive material.

27. The electrical apparatus of claim 21, wherein said base is composed of an electrically conductive material.

28. The electrical apparatus of claim 21, wherein said base is composed of an electrically insulative material.

29. The electrical apparatus of claim 27 wherein said base is electrically connected to one or more of either said anodes or said cathodes and electrically insulated from the other of said anodes or said cathodes.

30. The electrical apparatus of claim 21 further including an adhesive affixing said LEDs to said base.
